(19) United States
(12) Patent Application Publication
(10) Pub. No.: US 2021/0167257 A1
(43) Pub. Date: Jun. 3, 2021

(54) LIGHT CONVERSION MATERIAL, PRODUCING METHOD THEREOF, LIGHT-EMITTING DEVICE AND BACKLIGHT MODULE EMPLOYING THE SAME

(71) Applicant: Lextar Electronics Corporation, Hsinchu (TW)

(72) Inventors: Yi-Ting TSAI, Hsinchu (TW); Hung-Chia WANG, Hsinchu (TW); Hung-Chun TONG, Hsinchu (TW); Yu-Chun LEE, Hsinchu (TW); Tzong-Liang TSAI, Hsinchu (TW)

(21) Appl. No.: 17/013,851

(22) Filed: Sep. 7, 2020

(30) Foreign Application Priority Data
Nov. 29, 2019 (TW) 108143787
Aug. 17, 2020 (TW) 109127962

(51) Int. Cl. H01L 33/50; H01L 33/00; G02F 1/13357

(52) U.S. Cl. CPC H01L 33/504; H01L 2933/0041; G02F 1/133603; H01L 33/005

(57) ABSTRACT

A light conversion material includes a general formula and complies with a condition. The general formula is MmAaCcEe:ESxREy. M is at least one element selected from a group, and 2≤m≤3. A is at least one element selected from a group, and 0.01≤a≤1. C is at least one element selected from a group, and 1≤c≤9, E is at least one element selected from a group, and 5≤e≤7. ES is at least one element selected from a group, and 0≤x≤3. RE is at least one element selected from a group, and 0≤y≤3. The condition (2) is m+x+y=3.

### CROSS-REFERENCE TO RELATED APPLICATION

This application claims priority to Taiwan Application Serial Number 108143787, filed Nov. 29, 2019, and Taiwan Application Serial Number 109127962, filed Aug. 17, 2020, which are herein incorporated by reference.

### BACKGROUND

### Field of Invention

The present disclosure relates to a light conversion material, a producing method thereof, a light-emitting device, and a backlight module employing the same, and more particularly, the light conversion material is a green-emitting material.

### Description of Related Art

In recent years, backlight displays have been developed rapidly and their applications have become quite popular. Additionally, many products have gradually been following the modern tendency towards high technology and high specifications. However, current light-emitting diodes disposed in backlight displays mostly have problems about color purity, gamut coverage and lumen efficacy due to the physical limitations of materials.

For instance, a green-emitting material having a wavelength of about 531 nm is commonly used to achieve wide gamut coverage in order to approach the maximum stimulus value (about 555 nm) of the human eye, but the lumen efficacy of the green-emitting material is low in contrast.

Accordingly, developing a light conversion material which provides better solutions for the aforementioned problems becomes an important issue to be solved by those in the industry.

### SUMMARY

An aspect of the disclosure is to provide a light conversion material which can effectively solve the aforementioned problems.

According to an embodiment of the present disclosure, a light conversion material includes a general formula (1) and complies with a condition (2). The general formula (1) is MₘAₐC_{c}Eₑ:ESₓRE_{y}. M is at least one element selected from a group consisting of Ca, Sr, and Ba, and 2≤m≤3. A is at least one element selected from a group consisting of Mg, Mn, Zn, and Cd, and 0.01≤a≤1. C is at least one element selected from a group consisting of Si, Ge, Ti, and Hf, and 1≤c≤9, E is at least one element selected from a group consisting of O, S, and Se, and 5≤e≤7. ES is at least one element selected from a group consisting of divalent Eu, Sm, and Yb, and 0≤x≤3. RE is at least one element selected from a group consisting of trivalent Ce, Pr, Nd, Sm, Eu, Gd, Tb, Dy, Ho, Er, and Tm, and 0≤y≤3. The condition (2) is m+x+y=3.

In an embodiment of the disclosure, the light conversion material is configured to be excited by blue light or ultraviolet light to emit light, and a peak wavelength of the light is ranging from about 480 nm to about 580 nm.

In an embodiment of the disclosure, the light conversion material further complies with a condition (3). The condition (3) is that the light has a maximum intensity, a difference between a maximum wavelength λ₁ₘₐₓ and a minimum wavelength λ₁ₘᵢₙ of the light is a′ when an intensity of the light is 50% of the maximum intensity, and another difference between a maximum wavelength λ₂ₘₐₓ and a minimum wavelength λ₂ₘᵢₙ of the light is b′ when an intensity of the light is 10% of the maximum intensity, and 2.5a′≤b′≤7a′.

In an embodiment of the disclosure, the light conversion material includes a polycrystalline structure.

An aspect of the disclosure is to provide a light-emitting device. The light-emitting device includes a light source and a light conversion material. The light source emits blue light or ultraviolet light. The light conversion material excited by the blue light or the ultraviolet light to emit green light includes a general formula (1) and complies with a condition (2). The general formula (1) is MₘAₐC_{c}Eₑ:ESₓRE_{y}. M is at least one element selected from a group consisting of Ca, Sr, and Ba, and 2≤m≤3. A is at least one element selected from a group consisting of Mg, Mn, Zn, and Cd, and 0.01≤a≤1. C is at least one element selected from a group consisting of Si, Ge, Ti, and Hf, and 1≤c≤9, E is at least one element selected from a group consisting of O, S, and Se, and 5≤e≤7. ES is at least one element selected from a group consisting of divalent Eu, Sm, and Yb, and 0≤x≤3. RE is at least one element selected from a group consisting of trivalent Ce, Pr, Nd, Sm, Eu, Gd, Tb, Dy, Ho, Er, and Tm, and 0≤y≤3. The condition (2) is m+x+y=3.

In an embodiment of the disclosure, the light conversion material of the light-emitting device further complies with a condition (3). The condition (3) is that the light has a maximum intensity, a difference between a maximum wavelength λ₁ₘₐₓ and a minimum wavelength λ₁ₘᵢₙ of the light is a′ when an intensity of the light is 50% of the maximum intensity, and another difference between a maximum wavelength λ₂ₘₐₓ and a minimum wavelength λ₂ₘᵢₙ of the light is b′ when an intensity of the light is 10% of the maximum intensity, and 2.5≤a′≥b′≤7a′.

In an embodiment of the disclosure, the light conversion material of the light-emitting device includes a polycrystalline structure.

In an embodiment of the disclosure, the light conversion material is further mixed with a red-emitting material when the light source emits the blue light.

In an embodiment of the disclosure, the light conversion material is mixed with a red-emitting material and a green-emitting material when the light source emits the blue light.

In an embodiment of the disclosure, the light conversion material is further mixed with a red-emitting material and a blue-emitting material when the light source emits the ultraviolet light.

In an embodiment of the disclosure, the light conversion material is further mixed with a red-emitting material, a blue-emitting material, and a green-emitting material when the light source emits the ultraviolet light.

An aspect of the disclosure is to provide a backlight module including the aforementioned light-emitting device.

An aspect of the disclosure is to provide a producing method for producing the light conversion material aforementioned. The producing method includes: producing a first mixture by raw materials of M, A, C, and E according to the general formula (1); performing a first high-temperature process to the first mixture to produce a first product; producing a second mixture by the first product and raw materials of at least one of ES and RE according to the general formula (1); and performing a second high-temperature process to the second mixture under a reducing atmosphere to produce the light conversion material.

In an embodiment of the disclosure, the producing method further includes that performing a first low-temperature process to the first mixture to grow a seed crystal before performing the first high-temperature process to the first mixture.

In an embodiment of the disclosure, the first high-temperature process is a sintering process ranging from about 200° C. to about 600° C.

In an embodiment of the disclosure, the second high-temperature process is a calcination process ranging from about 800° C. to about 1400° C.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an excitation spectrum diagram of a light conversion material regarding an embodiment in the present disclosure.

FIG. 1A is an excitation spectrum comparison diagram showing the light conversion material diagram in FIG. 1, β-sialon phosphor powder, and YAG-phosphor powder.

FIG. 1B is a color coordinate comparison diagram showing the light conversion material shown in FIG. 1 and β-sialon phosphor powder.

FIG. 2 is a flowchart showing a producing method for producing the light conversion material shown in FIG. 1.

FIG. 2A is a flowchart showing an improved method of the producing method shown in FIG. 2.

FIG. 3 is a SEM image of the light conversion material produce by the method shown in FIG. 2.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “in some embodiments” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The present disclosure provides a light conversion material having high color purity. The light conversion material includes a general formula (1) and complies with a condition (2). The general formula (1) is MₘAₐC_{c}Eₑ:ESₓRE_{y}. M is at least one element selected from a group consisting of Ca, Sr, and Ba, and 2≤m≤3. A is at least one element selected from a group consisting of Mg, Mn, Zn, and Cd, and 0.01≤a≤1. C is at least one element selected from a group consisting of Si, Ge, Ti, and Hf, and 1≤c≤9, E is at least one element selected from a group consisting of O, S, and Se, and 5≤e≤7. ES is at least one element selected from a group consisting of divalent Eu, Sm, and Yb, and 0≤x≤3. RE is at least one element selected from a group consisting of trivalent Ce, Pr, Nd, Sm, Eu, Gd, Tb, Dy, Ho, Er, and Tm, and 0≤y≤3. The condition (2) is m+x+y=3. The composition and the proportion of the light conversion material can be adjusted by users so as to control wavelengths and color purity of light emitted by the excited light conversion material. Therefore, the wavelengths of the light emitted by the light conversion material in the present disclosure can be changed.

A group consisting of divalent Eu, Sm, and Yb refers to a group consisting of Eu²⁺, Sm²⁺, and Yb²⁺. A group consisting of trivalent Ce, Pr, Nd, Sm, Eu, Gd, Tb, Dy, Ho, Er, and Tm refers to a group consisting of Ce³⁺, Pr³⁺, Nd³⁺, Sm³⁺, Eu³⁺, Gd³⁺, Tb³⁺, Dy³⁺, Ho³⁺, Er³⁺, and Tm³⁺.

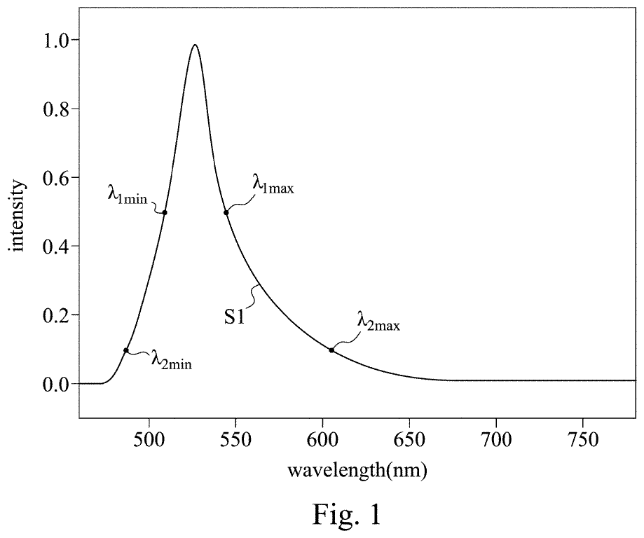

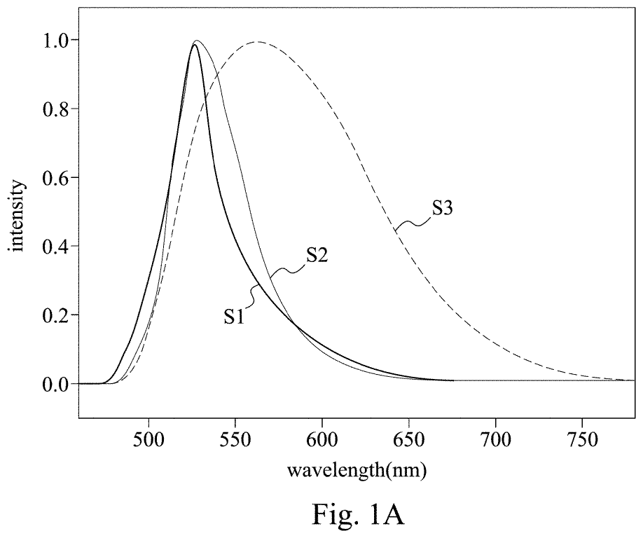

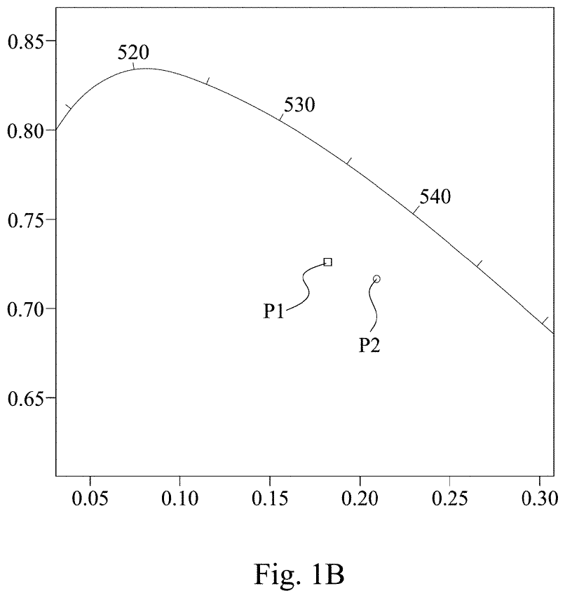

Reference is made to FIG. 1. FIG. 1 is an excitation spectrum diagram of a light conversion material regarding an embodiment in the present disclosure. The horizontal axis in the FIG. 1 represents light wavelengths. The vertical axis in the FIG. 1 represents light intensities (1.0 represents a maximum light intensity). In some embodiments in the present disclosure, the light conversion material is configured to be excited by blue light or ultraviolet light to emit green light having a peak wavelength ranging from about 480 nm to about 580 nm, wherein a preferred peak wavelength of the green light ranges from about 520 nm to about 540 nm. The blue light and the ultraviolet light may be respectively emitted by a blue light-emitting diode and an ultraviolet light-emitting diode, and the present disclosure is not limited in this respect. Moreover, a difference between a maximum length λ₁ₘₐₓ and a minimum length λ₁ₘᵢₙ of the light conversion material is small when the intensity of the green light is 50% of the maximum intensity, so that the light conversion material has good lumen efficacy and the green light emitted thereof has outstanding color purity.

In some embodiments in the present disclosure, the light conversion material complies with a condition (3). The condition (3) is that the green light has a maximum intensity, and a difference between a maximum wavelength λ₁ₘₐₓ and a minimum wavelength λ₁ₘᵢₙ of the green light is a′ when an intensity of the green light is 50% of the maximum intensity, another difference between a maximum wavelength λ₂ₘₐₓ and a minimum wavelength λ₂ₘᵢₙ of the green light is b′ when the intensity of the green light is 10% of the maximum intensity, wherein 2.5a′≤b′≤7a′. Therefore, differences between maximum intensities and minimum intensities of the green light in different intensities are small. Moreover, a′ represents a full wave half maximum (FWHM), wherein 30 nm≤a′<50 nm. Thus, the green light emitted by the light conversion material in the present disclosure has a narrow FWHM. It can be known that the light conversion material has good lumen efficacy and the green light emitted thereof has high color purity.

Moreover, in some embodiments of the present disclosure, the light conversion material has a polycrystalline structure and includes at least one polycrystalline phase.

Reference is made to FIG. 1A. FIG. 1A is an excitation spectrum comparison diagram showing the light conversion material diagram in FIG. 1, β-sialon phosphor powder, and yttrium aluminium garnet (YAG) phosphor powder. The horizontal axis shown in the FIG. 1A represents light wavelengths. The vertical axis shown in the FIG. 1A represents light intensities (1.0 represents a maximum light intensity). The curve S1 represents the light conversion material in the present disclosure. The curve S2 represents β-sialon phosphor powder. The curve S3 represents YAG phosphor powder. FIG. 1A shows that a full width at half maximum (FWHM) of the green light emitted by the light conversion material in the present disclosure is smaller than FWHM of the light emitted by the β-SiAlON phosphor powder and the YAG phosphor powder. As can be known from the above information, the light conversion material in the present disclosure has better lumen efficacy, and the green light emitted thereof has high color purity.

Reference is made to FIG. 1B. FIG. 1B is a CIE color coordinate comparison diagram showing color coordinates of the light conversion material in the FIG. 1 and β-sialon phosphor powder. The point P1 represents a color coordinate (0.1861, 0.7336) of the green light emitted from the light conversion material in the present disclosure. The point P2 represents a color coordinate (0.2138, 0.7285) of light emitted from the β-sialon phosphor powder. Based on the comparison between the point P1 and the point P2, the green light emitted from the light conversion material in the present disclosure has higher color purity than the light emitted from β-sialon phosphor powder.

Some embodiments in the present disclosure relate to a light-emitting device. The light-emitting device includes a light source and a light conversion material, and the light source is configured to emit blue light or ultraviolet light. The light conversion material is excited by the blue light or the ultraviolet light to emit green light having a peak wavelength ranging from about 480 nm to about 580 nm, wherein a preferred peak wavelength of the green light ranges from about 520 nm to about 540 nm. The light conversion material includes a general formula (1) and complies with a condition (2). The general formula (1) is MₘAₐC_{c}Eₑ:ESₓRE_{y}. M is at least one element selected from a group consisting of Ca, Sr, and Ba, and 2≤m≤3. A is at least one element selected from a group consisting of Mg, Mn, Zn, and Cd, and 0.01≤a≤1. C is at least one element selected from a group consisting of Si, Ge, Ti, and Hf, and 1≤c≤9. E is at least one element selected from a group consisting of O, S, and Se, and 5≤e≤7. ES is at least one element selected from a group consisting of divalent Eu, Sm, and Yb, and 0≤x≤3. RE is at least one element selected from a group consisting of trivalent Ce, Pr, Nd, Sm, Eu, Gd, Tb, Dy, Ho, Er, and Tm, and 0≤y≤3. The condition (2) is m+x+y=3. Specifically, the light-emitting device may be a light-emitting diode (LED).

Reference is made back to FIG. 1. In regard to the light-emitting device in some embodiments of the present disclosure, the light conversion material complies with a condition (3). The condition (3) is that the green light has a maximum intensity, and a difference between a maximum wavelength λ₁ₘₐₓ and a minimum wavelength λ₁ₘᵢₙ of the green light is a′ when an intensity of the green light is 50% of the maximum intensity, another difference between a maximum wavelength λ₂ₘₐₓ and a minimum wavelength λ₂ₘᵢₙ of the green light is b′ when an intensity of the green light is 10% of the maximum intensity, and 2.5a′≤b′≤7a′. Moreover, a′ represents a full wave half maximum (FWHM), wherein 30 nm≤a′≤50 nm, and thus the green light emitted by the light conversion material in the present disclosure has a narrow FWHM.

In regard to the light-emitting device in some embodiments of the present disclosure, the light conversion material has a polycrystalline structure and includes at least one polycrystalline phase.

In regard to the light-emitting device in some embodiments of the present disclosure, the light conversion material is further mixed with a red-emitting material when the light source emits the blue light. The light conversion material in the present disclosure and the red-emitting material are excited by the blue light to emit green light and red light in order to be combined with the blue light to become white light.

In regard to the light-emitting device in some embodiments of the present disclosure, the light conversion material is further mixed with a red-emitting material and a green-emitting material when the light source emits the blue light. The light conversion material in the present disclosure, the green-emitting material, and the red-emitting material are excited by the blue light to emit green light and red light in order to be combined with the blue light to become white light.

In regard to the light-emitting device in some embodiments of the present disclosure, the light conversion material is further mixed with a red-emitting material and a blue-emitting material when the light source emits the ultraviolet light. The light conversion material in the present disclosure, the red-emitting material, and the blue-emitting material are excited by the ultraviolet light to emit green light, red light, and blue light in order to be combined together to become white light.

In regard to the light-emitting device in some embodiments of the present disclosure, the light conversion material is further mixed with a red-emitting material, a blue-emitting material, and a green-emitting material when the light source emits the ultraviolet light. The light conversion material in the present disclosure, the green-emitting material, the red-emitting material, and the blue-emitting material are excited by the ultraviolet light to emit green light, red light, and blue light in order to be combined together to emit white light.

In regard to the light-emitting device in some embodiments of the present disclosure, the red-emitting material may be red-emitting phosphor powder, such as nitride phosphor powder ((Sr,Ca)AlSiN₃:Eu, Ca₂Si₅N₈:Eu²⁺, and Sr(LiAl₃N₄):Eu²⁺) and manganese-doped red fluoride phosphor powder (K₂GeF₆:Mn⁴⁺, K₂SiF₆:Mn⁴⁺, and K₂TiF₆:Mn⁴⁺), but the present disclosure is not limited in this respect. The red-emitting material may also be red-emitting Quantum Dots, such as indium phosphide (InP) Quantum Dots, cadmium selenide (CdSe) Quantum Dots, and all-inorganic perovskite Quantum Dots having a general formula: CsPb(Br_{1-c′}I_{c′})₃ and 0.5≤c′≤1. The present disclosure is not limited in this respect.

In regard to the light-emitting device in some embodiments of the present disclosure, the green-emitting material may be green-emitting phosphor powder, such as lutetium aluminium garnet (LuAG) phosphor powder, YAG phosphor powder, β-SiAlON phosphor powder, and silicate phosphor powder, but the present disclosure is not limited in this respect. The green-emitting material may also be green-emitting Quantum Dots, such as CdSe Quantum Dots, cadmium sulfide (CdS) Quantum Dots, cadmium telluride (CdTe) Quantum Dots, InP Quantum Dots, indium nitride (InN) Quantum Dots, indium aluminium nitride (AlInN) Quantum Dots, indium gallium nitride (InGaN) Quantum Dots, aluminium gallium nitride (AlGaInN) Quantum Dots, copper indium gallium selenide (CuInGaSe) Quantum Dots, and all-inorganic perovskite Quantum Dots having a general formula: CsPb(Br_{1-d′}I_{d′})₃ and 0≤d′<0.5. The present disclosure is not limited in this respect.

In regard to the light-emitting device in some embodiments of the present disclosure, the blue-emitting material may be BAM (BaMgAl₁₀O₁₇:Eu²⁺) phosphor powder, but the present disclosure is not limited in this respect. The blue-emitting material may also be blue emitting Quantum Dots, such as CdSe Quantum Dots, zinc selenide (ZnSe) Quantum Dots, and all-inorganic perovskite Quantum Dots having a general formula: CsPb(Cl_{e′}Br_{1-e′})₃ and 0<e′≤1. The present disclosure is not limited in this respect.

The present disclosure also provides a backlight module including a light-emitting device, and the details about the light-emitting device herein are basically the same as the aforementioned light-emitting device. Specifically, the backlight module is disposed in a Liquid-Crystal Display (LCD) to provide a backlight source.

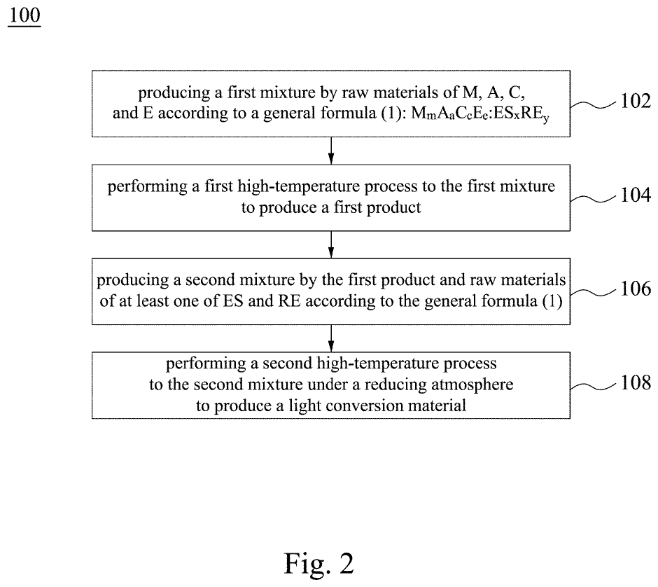

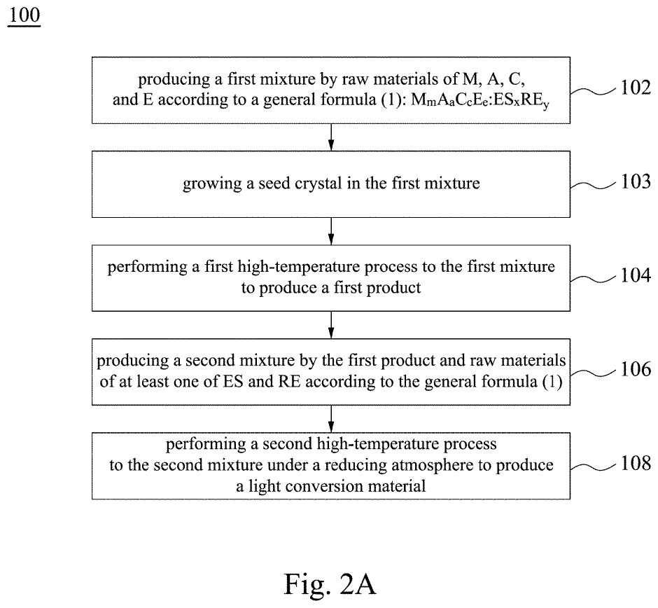

Reference is now made to FIG. 2. The present disclosure also provides a producing method 100 including the following steps in order to produce the aforementioned light conversion material in the present disclosure. The producing method 100 begins with step 102: producing a first mixture by raw materials of M, A, C, and E according to the general formula (1) of the light conversion material. The producing method 100 continues with step 104: performing a first high-temperature process to the first mixture to produce a first product. The producing method 100 continues with step 106: producing a second mixture by the first product and raw materials of at least one of ES and RE according to the general formula (1) of the light conversion material. Finally, the producing method 100 continues with step 108: performing a second high-temperature process to the second mixture under a reducing atmosphere to produce the light conversion material.

Specifically, the raw materials of the elements M, A, C, and E may be oxygen compounds thereof, sulfur compounds thereof, carbonate compounds thereof, or salts thereof. For instance, if M in the formula (1) represents Ba, the raw material thereof may be barium oxide (BaO) or barium carbonate (BaCO₃). Moreover, the first high-temperature process is a sintering process ranging from about 200° C. to about 600° C. in the step 104. The second high-temperature process is a calcination process ranging from about 800° C. to about 1400° C. in the step 108.

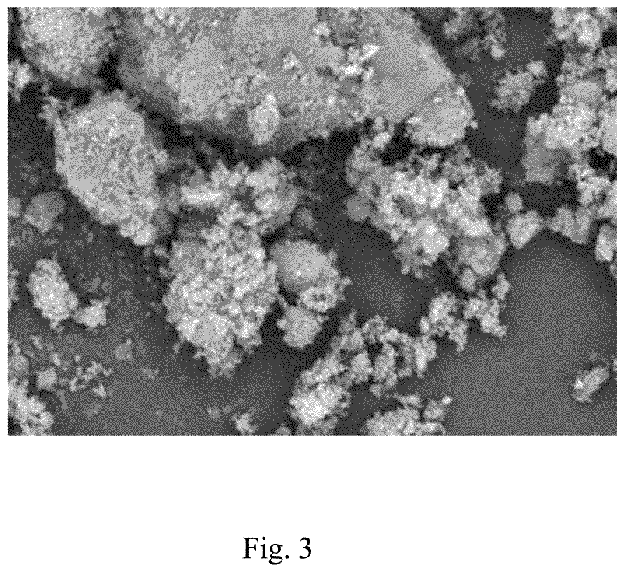

Reference is now made to FIG. 2 and FIG. 3. FIG. 3 is a SEM image of the light conversion material produce by the method shown in FIG. 2, and a SEM image refers to a microstructure image taken by a Scanning Electron Microscope through scanning surface of an analyte. In an embodiment in the present disclosure, the producing method 100 begins with step 102: producing a first mixture by dissolving about 5.18 grams of raw materials from Group 1A (such as sodium fluoride (NaF) or sodium carbonate (Na₂CO₃)), about 16.58 grams of raw materials from Group 2A (such as barium oxide (BaO), barium carbonate (BaCO₃), or strontium carbonate (SrCO₃)), about 5.53 grams of raw materials from Group 4A (such as silicon oxide (SiO₂)), and about 1.72 grams of raw materials from Group 2B (such as zinc oxide (ZnO) or zinc sulfide (ZnS)) in a dilute nitric acid solution. The producing method 100 continues with step 104: producing a first product by performing a sintering process from about 200° C. to about 600° C. to the first mixture for about 144 hours. The producing method 100 continues with step 106: producing a second mixture by adding an appropriate amount of silicon oxide (SiO₂) and europium oxide (Eu₂O₃) to the first product after the first product has been cooled down to room temperature and ground. The producing method 100 continues with step 108: producing the light conversion material by performing a calcination process for at least 24 hours to the second mixture under a reducing atmosphere. Finally, after the light conversion material is cooled down to room temperature, the light conversion material, which is composed of 2.8SiO₂-3.6BaO-0.8ZnS-0.05Eu₂O₃, as shown in FIG. 3 can be obtained.

Reference is made back to FIG. 2A. In some embodiments of the producing method 100 further include a step 103. The step 103 is performed after the step 102 and before the step 104 is started. Specifically, the producing method 100 further includes: performing a first low-temperature process to the first mixture to grow a seed crystal before performing the first high-temperature process to the first mixture. By growing a seed crystal in the first mixture in the step 103, time for the subsequent heat treatment can be reduced, thereby reducing costs and improving the quality of the light conversion material.

In summary, it is known from the above embodiments and contents that the present disclosure provides a light conversion material having a narrow spectral width, so that the light conversion material has good lumen efficacy and the green light emitted thereof has high color purity. Therefore, the light conversion material in the present disclosure can improve the lumen efficacy of a light-emitting device and a backlight module employing the same to emit light having higher color purity.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light conversion material, comprising a general formula (1) and complying with a condition (2), wherein the general formula (1) is MₘAₐC_{c}Eₑ:ESₓRE_{y}, M is at least one element selected from a group consisting of Ca, Sr, and Ba, wherein 2≤m≤3, A is at least one element selected from a group consisting of Mg, Mn, Zn, and Cd, wherein 0.01≤a≤1, C is at least one element selected from a group consisting of Si, Ge, Ti, and Hf, wherein 1≤c≤9, E is at least one element selected from a group consisting of O, S, and Se, wherein 5≤e≤7, ES is at least one element selected from a group consisting of divalent Eu, Sm, and Yb, wherein 0≤x≤3, and RE is at least one element selected from a group consisting of trivalent Ce, Pr, Nd, Sm, Eu, Gd, Tb, Dy, Ho, Er, and Tm, wherein 0≤y≤3, and the condition (2) is m+x+y=3.

2. The light conversion material of claim 1, wherein the light conversion material is configured to be excited by blue light or ultraviolet light to emit light, and a peak wavelength of the light is ranging from about 480 nm to about 580 nm.

3. The light conversion material of claim 2, further complying with a condition (3), wherein the condition (3) is that the light has a maximum intensity, a difference between a maximum wavelength λ₁ₘₐₓ and a minimum wavelength λ₁ₘᵢₙ of the light is a′ when an intensity of the light is 50% of the maximum intensity, and another difference between a maximum wavelength λ₂ₘₐₓ and a minimum wavelength λ₂ₘᵢₙ of the light is b′ when an intensity of the light is 10% of the maximum intensity, wherein 2.5a′≤b′≤7a′.

4. The light conversion material of claim 1, wherein the light conversion material comprises a polycrystalline structure.

5. A light-emitting device, comprising:
a light source emitting blue light or ultraviolet light; and
a light conversion material excited by the blue light or the ultraviolet light to emit light, comprising a general formula (1) and complying with a condition (2), wherein the general formula (1) is MₘAₐC_{c}Eₑ:ESₓRE_{y}, M is at least one element selected from a group consisting of Ca, Sr, and Ba, wherein 2 m 3, A is at least one element selected from a group consisting of Mg, Mn, Zn, and Cd, wherein 0.01≤a≤1, C is at least one element selected from a group consisting of Si, Ge, Ti, and Hf, wherein 1≤c≤9, E is at least one element selected from a group consisting of O, S, and Se, wherein 5≤e≤7, ES is at least one element selected from a group consisting of divalent Eu, Sm, and Yb, wherein 0≤x≤3, and RE is at least one element selected from a group consisting of trivalent Ce, Pr, Nd, Sm, Eu, Gd, Tb, Dy, Ho, Er, and Tm, wherein 0≤y≤3, and the condition (2) is m+x+y=3.

6. The light-emitting device of claim 5, wherein the light conversion material further complies with a condition (3), the condition (3) is that the light has a maximum intensity, and a difference between a maximum wavelength λ₁ₘₐₓ and a minimum wavelength λ₁ₘᵢₙ of the light is a′ when an intensity of the light is 50% of the maximum intensity, another difference between a maximum wavelength λ₂ₘₐₓ and a minimum wavelength λ₂ₘᵢₙ of the light is b′ when an intensity of the light is 10% of the maximum intensity, wherein 2.5a′≤b′≤7a′.

7. The light-emitting device of claim 5, wherein the light conversion material comprises a polycrystalline structure.

8. The light-emitting device of claim 5, wherein the light conversion material is further mixed with a red-emitting material when the light source emits the blue light.

9. The light-emitting device of claim 8, wherein the light conversion material is further mixed with a green-emitting material.

10. The light-emitting device of claim 5, wherein the light conversion material is further mixed with a red-emitting material and a blue-emitting material when the light source emits the ultraviolet light.

11. The light-emitting device of claim 10, wherein the light conversion material is further mixed with a green-emitting material.

12. A backlight module, comprising the light-emitting device of claim 5.

13. A producing method for producing the light conversion material of claim 1, the producing method comprising:
producing a first mixture by raw materials of M, A, C, and E according to the general formula (1) of the light conversion material;
performing a first high-temperature process to the first mixture to produce a first product;
producing a second mixture by the first product and raw materials of at least one of ES and RE according to the general formula (1) of the light conversion material; and
performing a second high-temperature process to the second mixture under a reducing atmosphere to produce the light conversion material.

14. The producing method of claim 13, wherein the first high-temperature process is a sintering process ranging from about 200° C. to about 600° C.

15. The producing method of claim 13, wherein the second high-temperature process is a calcination process ranging from about 800° C. to about 1400° C.

16. The producing method of claim 13, further comprising:
growing a seed crystal in the first mixture before performing the first high-temperature process to the first mixture.

17. The producing method of claim 16, wherein the first high-temperature process is a sintering process ranging from about 200° C. to about 600° C.

18. The producing method of claim 16, wherein the second high-temperature process is a calcination process ranging from about 800° C. to about 1400° C.
